(19) United States
(12) Patent Application Publication
(10) Pub. No.: US 2009/0196373 A1
(43) Pub. Date: Aug. 6, 2009

(54) SYSTEM FOR INCREASING RFID TAG READER SENSITIVITY

(75) Inventor: Lee SNOOK, Golden, CO (US)

Correspondence Address: LATHROP & GAGE LLP, 4845 PEARL EAST CIRCLE, SUITE 201, BOULDER, CO, 80301, US

(73) Assignee: SKYETEK, INC., Westminster, CO (US)

(21) Appl. No.: 12/364,400

(22) Filed: Feb. 2, 2009

Related U.S. Application Data
(60) Provisional application No. 61/025,117, filed on Jan. 31, 2008.

(51) Int. Cl. H03K 7/10; G08B 13/14

(52) U.S. Cl. 375/269; 340/572.1

(57) ABSTRACT

A system for increasing the sensitivity of a receiver in an RFID tag reader. The system includes a directional coupler which receives the signal transmitted by the reader and which receives a backscatter signal from the RFID tag. The output of the directional coupler includes a transmit reference signal and a combined signal comprising the received signal and a transmit leakage signal. A first feedback loop generates an amplitude-compensated reference signal including a transmit signal component having the same amplitude as the transmit leakage signal. A second feedback loop adjusts the phase angle of the amplitude-compensated reference signal to a phase angle 180 degrees out-of-phase with the combined signal, to generate a canceling signal which effectively cancels out the transmit leakage signal component of the combined signal thereby improving the signal-to-noise ratio thereof.

### RELATED APPLICATION

This application claims priority to U.S. Provisional Patent Application Ser. No. 61/025,117, filed Jan. 31, 2008, the disclosure of which is incorporated herein by reference.

### BACKGROUND

RFID (Radio-Frequency Identification) technology differs from conventional full duplex and simplex radio link communications in that the RFID transmitted and receive signals simultaneously occupy the same frequency and use the same antenna. The transmitted signal carrier can be as great as one watt, +30 dBm, and received signal levels may be as low as −60 dBm. A spurious free dynamic range of 90 dB or better is thus required by a receiver in order to process the received signal. A problem exists in that the transmitter carrier phase noise and adjacent channel power ratio may rise to a level that masks the receive signal sidebands, and which can overload a low noise amplifier inserted to improve the receiver's cascaded noise figure.

### BRIEF DESCRIPTION OF THE DRAWINGS

FIG. 1 is an exemplary diagram showing the circuit of the present system in the larger context of an RFID system;

FIG. 2 is an exemplary diagram of the present system; and

FIG. 3 is an exemplary diagram showing certain functional components of the present system.

### DETAILED DESCRIPTION

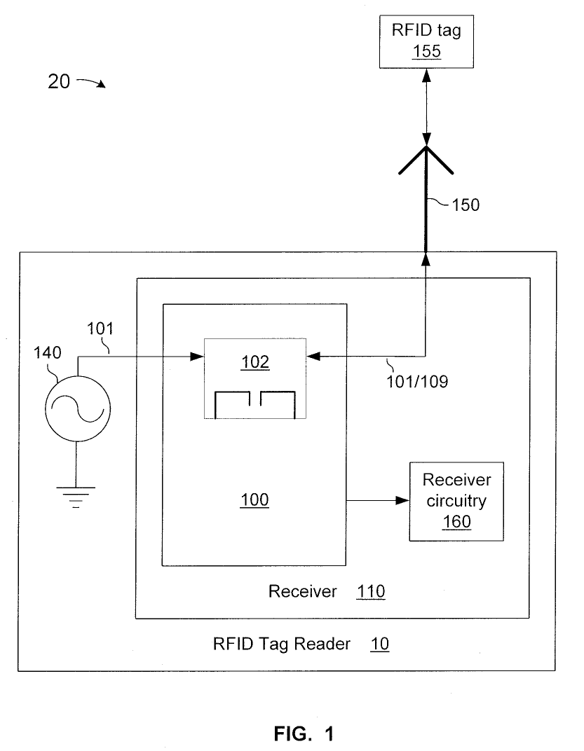

FIG. 1 is an exemplary diagram showing the RFID reader receiver circuit 100 of the present system in the larger context of an RFID system 20. As shown in FIG. 1, an RFID system employs an RFID ‘tag’ 155 and an RFID tag reader 10. Identification information is stored in the tag 155, which has its own antenna (not shown). The RFID reader 10 includes a transmitter 140, which transmits RF signals 101 to the RFID tag 155, and a receiver 110, which receives modulated backscattered RF signals 109 from the tag. Receiver 110 includes sensitivity-increasing circuit 100 and following section 160 of the receiver circuitry.

As explained in the Background section, the receiver section 110 of an RFID reader is required to have a dynamic range on the order of 90 dB. The presently disclosed system decreases the ratio between (1) the transmitted signal (the on-channel interferer) and the reflected backscatter signal over a broad range of antenna impedance mismatches in the receiver 110 used in the RFID reader 10.

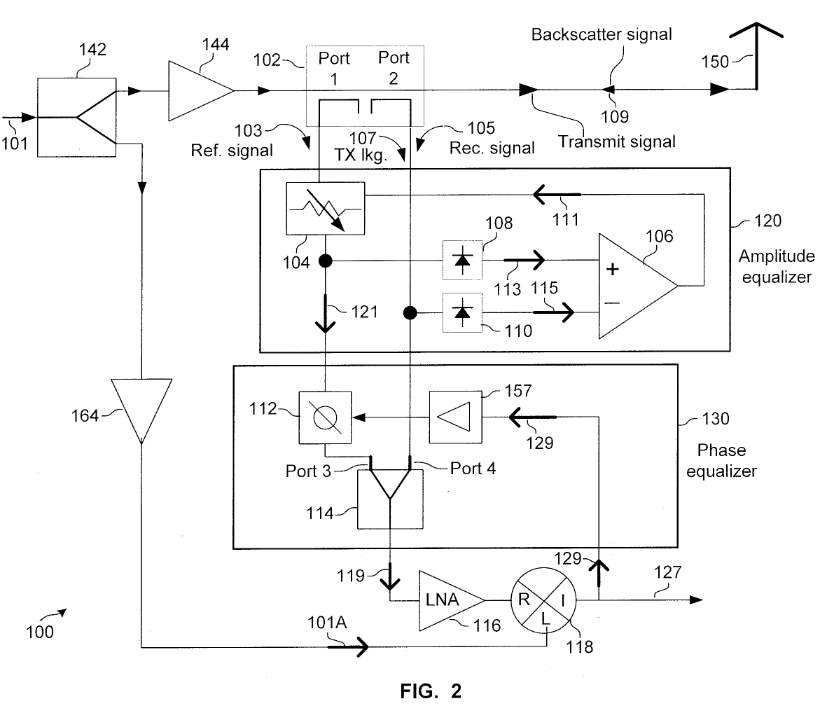

FIG. 2 is an exemplary high-level diagram of the present receiver sensitivity-increasing circuit 100, which functions to decrease the ratio of interfering transmit energy to receive energy at the input to the low noise amplifier (LNA) 116 driving the baseband signal output 127 to the following section 160 of the receiver circuit in RFID tag reader 10. As shown in FIG. 2, signal output 101 from transmitter 140 is split by splitter 142 into two signals. One of the transmitter output signals is fed through amplifier 164 into local oscillator port of mixer 118. The other signal from splitter 142 is fed through power amplifier 144 into port 1 of a high directivity directional coupler 102. Port 2 of coupler 102 receives the backscattered signal from an RFID tag via antenna 150.

If all of the directional coupler ports are perfectly matched to 50 ohms, the transmitted carrier signal 101 is attenuated by the directivity of the coupler plus the coupler port attenuation. If a 10 dB two port coupler with a directivity of 25 dB is used, then the received signal will be attenuated by 10 dB and the transmitted signal by 35 dB. For a transmitter power of 30 dBm and a receive signal at −60 dBm, at port 2, the receive signal is −70 dBm and the transmit leakage is −5 dBm. Under conditions where the directional coupler is not presented with a 50 ohm load, circuit 100 attenuates the transmit signal leakage 107 by adding a component of the transmit signal of the same amplitude and opposite phase angle at the combiner 114.

The use of a directional coupler 102 and two feedback loops 120/130, in the manner described herein, allows a low noise amplifier 116 to be used to increase the backscatter signal to transmit signal ratio, thereby increasing the cascaded noise figure of the receiver 110. This reader noise figure is increased only if the attenuated transmit signal does not increase to a level that drives the input of the LNA 116 near an input 1 dB compression point and thus decreases its gain. For example, If the LNA Input 1 dB compression point is −1 dBm, the transmitter leakage is 30 dBm−25 dB−10 dB=−5 dBm input level, which is an acceptable 4 dB below the LNA input 1 dB compression point.

Circuit 100 samples the forward-transmitted signal 101 at input port 1 and received signal 109 at port 2 of the coupler to respectively generate reference signal 103 at output port 1 and transmitter leakage signal 107 at output port 2 of the directional coupler 102. Note that the desired receive signal 105 is not nulled at this point due to the reverse directionality of the coupler.

As shown in FIG. 2, antenna 150 presents a load to output port 2 of the directional coupler 102. The antenna gamma magnitude and phase angle load presented to the directional coupler can present a mismatch to the 50 ohm coupler output port, thereby decreasing the directivity of the coupler 102. The transmit leakage, as a function of Gamma and Phase angle mismatch, ‘TX Leakage’, is shown in Table 1, below. Circuit 100 utilizes the two feedback loops 120/130 to attenuate the transmit signal leakage 107 by adjusting transmit reference signal 103 to a signal having the same amplitude and opposite phase angle as the transmit leakage signal 107, thereby effectively nulling out signal 107 at the input to the low noise amplifier 116. It should also be noted that the sideband phase noise level of signal 107 is high in amplitude relative to received signal 105. The present circuit 100 also decreases the transmitter-generated sideband phase noise of signal 107, which would otherwise mask signal 105.

Feedback loop 120 functions as an amplitude equalization loop which attenuates reference signal 103 by generating an amplitude-compensated reference output signal 121 having the same amplitude as the transmit leakage signal 107. Detectors 108 and 110 sample reference signal 103 and transmitter leakage signal 107 on respective output ports 1 and 2 of directional coupler 102. Sampled output signals 113 and 115 are fed into amplitude comparator 106, which generates an error voltage 111 that controls the attenuation of variable attenuator 104 so that both signals 113/115 are of equal magnitude.

Feedback loop 130 functions as a phase equalization loop which generates a canceling signal 119 with the opposite phase angle (i.e., with a phase angle which is 180 degrees out-of-phase with the transmit leakage signal 107) at the input to combiner 114. Combined transmitter signal 101A and leakage sine wave signals 103/107 generate a DC offset 129 at the output of the mixer 118. The DC level of signal 129 is a function of the phase angle between the transmitter signal 101A and leakage signal 107 amplitude and phase difference.

Phase shifter 112 sweeps through 360 degrees to an angle that forces the DC output voltage 129 of mixer 118 to essentially zero, thus effectively nulling out the transmit leakage signal component 107. Output voltage level 129 is measured by a voltage sensor in controller circuit 157, which controls phase shifter 112 accordingly. The resultant signal 119, having significantly attenuated transmit signal leakage and transmitter-generated sideband phase noise components, is fed into low noise amplifier 116. Signal 119 is combined with transmitter output signal 101A by mixer 118 to provide receiver baseband signal output 127.

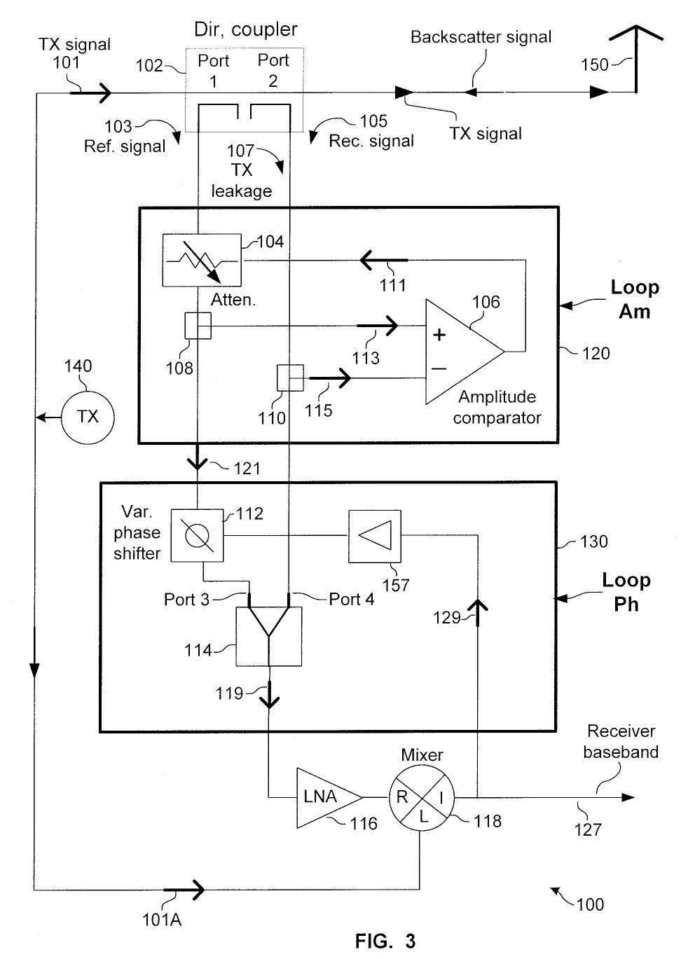

FIG. 3 is an exemplary diagram showing high-level functional components of the present system. As shown in FIG. 3, circuit 100 comprises an RFID transmitter 140, an antenna 150, a directional coupler 102 and two feedback loops, Am (120) and Ph (130).

As described above, amplitude equalization feedback loop Am comprises a variable attenuator 104, two detectors 108/110, and an amplitude comparator 106. Phase reversal feedback loop Ph includes variable phase shifter 112 and combiner 114, with the loop being completed through LNA 116 and mixer 118. Feedback loops Am and Ph can either be analog or digitally controlled.

Circuit 100 attenuates the transmit signal leakage 107 by generating a signal 121 with an amplitude equal to transmit leakage signal 107, via loop Am. Signal 121 is then adjusted to have a phase angle opposite of that of transmit leakage signal 107, via loop Ph, to generate signal 119, which essentially comprises the received signal 105 and the attenuated transmitter signal leakage 107. Signal 119 is input to low noise amplifier 116, and combined with adjusted transmitter output signal 101A by mixer 118 to provide receiver baseband signal output 127.

Table 1, below, describes a test procedure for circuit 100, and was compiled as follows:
1. A magnitude- and phase-adjustable Gamma load was connected to the antenna port. This load presented VSWR of 1.05, 1.2, 1.6, and 2.1:1 at phase angles from 0 to 360 in 45 degree increments. For this test, a stretch line was used as a phase shifter.
2. A 20 dB directional coupler placed between the antenna port and load was used to measure the output power.
3. The combiner was removed and two spectrum analyzers measured the power levels at ports 3 and 4.
4. The control port of the attenuator voltage, Vca, was then varied until the power levels were equal. The voltage Vca was then recorded for each VSWR and phase angle.
5. The combiner was then reconnected and the phase shifter was adjusted for a transmitter carrier leakage null. The phase shift, L2 in centimeters, and nulled carrier level, Tx Leakage Nulled, was then recorded.
6. A signal was then injected into port 1 of the external directional coupler through a 20 dB pad.
7. The signal level was decreased until the phase jitter at the output of the baseband comparator reached 10% of the square wave bit period. This level was then recorded as the receiver compensated sensitivity, Sensitivity dBm(Comp), for each VSWR and Phase Angle.
8. The nulling circuit was then removed and the sensitivity remeasured for each VSWR and Phase Angle, Sensitivity dBm.

TABLE 1
RFID Reader Sensitivity Improvement Data
Transmit Carrier Leakage Cancellation Technique
Po = 27 dBm
910 Mhz

| Phase Angle | 0 | −45 | −90 | −135 | 180 | 135 | 90 | 45 | |
|---|---|---|---|---|---|---|---|---|---|
| VSWR = 1.05 (Attn = 10) | | | | | | | | | |
| Load Phase L1(cm) | 6.4 | 7.4 | 8.4 | 9.5 | 10.5 | 11.5 | 12.6 | 13.6 | |
| Tx Leakage (Port 2) | −16 | −17 | −11 | −8 | −7 | −7 | −8.5 | −11 | |
| Vca | 2.53 | 2.62 | 1.94 | 1.49 | 1.35 | 1.35 | 1.51 | 1.91 | |
| Phase Shifter L2(cm) | 3.5 | 0.8 | 0.5 | 1.2 | 2.1 | 2.8 | 3.5 | 3.8 | |
| Tx Leakage Nulled | −40 | −42 | −38 | −34 | −35 | −37 | −40 | −48 | |
| Sensitivity dBm | −58 | −65 | −64 | −64 | −54 | −63 | −66 | −66 | −62.5 |
| Sensitivity dBm(Comp) | −70 | −71 | −71 | −70 | −69 | −69 | −68 | −70 | −69.75 |
| Difference = | −12 | −6 | −7 | −6 | −15 | −6 | −2 | Avg Diff = | 7.25 |
| VSWR = 1.2 (Attn = 6) | | | | | | | | | |
| Tx Leakage (Port 2) | −11.7 | −11.8 | −6.8 | −3.7 | −2.6 | −2.7 | −4 | −7 | |
| Vca | 1.99 | 2.01 | 1.35 | 1.03 | 0.96 | 0.96 | 1.07 | 1.34 | |
| Phase Shifter L2(cm) | 8.1 | 12.4 | 15.3 | 17.2 | 18.6 | 19.8 | 21.1 | 22.4 | |
| Tx Leakage Nulled | −36 | −43 | −43 | −37 | −40 | −39 | −43 | −43 | |
| Sensitivity dBm | −67 | −64 | −59 | −61 | −49 | −60 | −64 | −64 | −61 |
| Sensitivity dBm(Comp) | −68 | −70 | −69 | −70 | −67 | −65 | −64 | −66 | −67.375 |
| Difference = | −1 | −6 | −10 | −9 | −18 | −5 | 0 | Avg Diff = | 6.375 |
| VSWR = 1.6 (Attn = 2) | | | | | | | | | |
| Tx Leakage (Port 2) | 0 | 0.3 | 1.5 | 2.6 | 3 | 2.9 | 2.3 | 1 | |
| Vca | 0.75 | 0.74 | 0.63 | 0.5 | 0.43 | 0.43 | 0.51 | 0.65 | |
| Phase Shifter L2(cm) | 9.6 | 12.3 | 14.7 | 16.8 | 18.6 | 20 | 22 | 23.8 | |
| Tx Leakage Nulled | −43 | −37 | −37 | −33 | −37 | −36 | −43 | −41 | |
| Sensitivity dBm | −54 | −52 | −51 | −50 | −50 | −55 | −52 | −53 | −52.125 |
| Sensitivity dBm(Comp) | −65 | −62 | −62 | −65 | −63 | −61 | −61 | −62 | −62.625 |
| Difference = | −11 | −10 | −11 | −15 | −13 | −6 | −9 | Avg Diff = | 10.5 |
| VSWR = 2.1 (Attn = 0) | | | | | | | | | |
| Tx Leakage (Port 2) | 5.3 | 5.5 | 6.1 | 6.4 | 6.3 | 6.3 | 6 | 5.4 | |
| Vca | 0.19 | 0.17 | 0.12 | 0.02 | 0.01 | 0 | 0.02 | 0.14 | |
| Phase Shifter L2(cm) | 9.5 | 12 | 14.3 | 16.5 | 18.3 | 20 | 21.9 | 24 | |
| Tx Leakage Nulled | −50 | −34 | −26 | −32 | −26 | −33 | −50 | −50 | |
| Sensitivity dBm | −46 | −47 | −50 | −50 | −44 | −51 | −53 | −52 | −49.125 |
| Sensitivity dBm(Comp) | −63 | −64 | −59 | −62 | −63 | −57 | −58 | −62 | −61 |
| Difference = | −17 | −17 | −9 | −12 | −19 | −6 | −5 | Avg Diff = | 11.875 |

While preferred embodiments of the disclosed subject matter have been described, so as to enable one of skill in the art to practice the disclosed subject matter, the preceding description is intended to be exemplary only, and should not be used to limit the scope of the disclosure, which should be determined by reference to the following claims.

What is claimed is:

1. A system for increasing sensitivity of a receiver in an RFID tag reader generating a transmitted signal and receiving a received signal from an RFID tag, the system comprising:
a directional coupler receiving the transmitted signal and the received signal on opposite input ports thereof to generate a transmit reference signal and a combined signal, comprising the received signal and a transmit leakage signal, at respective output ports of the directional coupler;
a first feedback loop for generating an amplitude-compensated reference signal including a transmit signal component having the same amplitude as the transmit leakage signal; and
a second feedback loop for adjusting the phase angle of the amplitude-compensated reference signal to a phase angle 180 degrees out-of-phase with the combined signal, to generate a canceling signal which essentially nulls the transmit leakage signal component of the combined signal.

2. The system of claim 1, wherein the first feedback loop receives the reference signal and the combined signal as input, and the second feedback loop receives the amplitude-compensated reference signal and the combined signal as input.

3. The system of claim 1, including a low-noise amplifier, wherein:
the first feedback loop includes a variable attenuator, a first and a second sampling detector, and a comparator, wherein the reference signal out put from the directional coupler is input to the variable attenuator to provide an attenuated reference signal;
wherein the attenuated reference signal and the combined signal are sampled and respective signal samples thereof are separately input to the comparator;
wherein the output of the comparator is coupled to the variable attenuator to control attenuation of the attenuated reference signal such that the signal samples have equal amplitude; and
the second feedback loop includes a variable phase shifter and a signal combiner coupled to a controller circuit, wherein the phase shifter is coupled to the output of the attenuator, and the combined signal and the output of the phase shifter are input to the combiner;
wherein the output of the combiner is input to the low-noise amplifier, the output from which is input, via a mixer 118, to the controller circuit to adjust a phase angle of the attenuated reference signal to an angle 180 degrees out-of phase with respect to the transmit leakage signal component of the combined signal, thereby essentially canceling out the transmit leakage signal component of the combined signal.

4. A system for increasing sensitivity of a receiver in an RFID tag reader including a low-noise amplifier, wherein the reader generates a transmitted signal and receives a received signal from an RFID tag, comprising:
a directional coupler, including a first port and a second port into which the transmitted signal and the received signal are respectively input, wherein the received signal is coupled to the first port, and the transmitted signal is coupled to the second port, and wherein a reference signal part of the transmitted signal is transmitted through the directional coupler to a first output port, and the received signal and a transmit leakage signal are transmitted through the directional coupler, as a combined signal, to a second output port;
a first feedback loop, coupled to the first output port and to the second output port, including a variable attenuator, a first and a second sampling detector, and a comparator, wherein the reference signal out put from the first output port is input to a variable attenuator to provide an attenuated reference signal as output;
wherein the attenuated reference signal and the combined signal are sampled and respective signal samples thereof are separately input to the comparator;
wherein the output of the comparator is coupled to the variable attenuator to control attenuation of the attenuated reference signal such that the signal samples have equal amplitude;
a second feedback loop including a variable phase shifter and a controller circuit therefor, and a signal combiner, wherein the phase shifter is coupled to the output of the variable attenuator, and the combined signal and the output of the phase shifter are input to the combiner;
wherein the output of the combiner is input to the low-noise amplifier, and a signal comprising output from the amplifier is input to the controller circuit to adjust a phase angle of the attenuated reference signal to an angle 180 degrees out-of phase with respect to the transmit leakage signal, thereby canceling out the transmit leakage signal component of the combined signal.

5. A method for increasing sensitivity of a receiver in an RFID tag reader generating a transmitted signal and receiving a received signal from an RFID tag, the method comprising:
coupling the transmitted signal and the received signal to separate input ports of a directional coupler to generate a transmit reference signal and a combined signal, comprising the received signal and a transmit leakage signal, at respective output ports of the directional coupler;
generating an amplitude-compensated reference signal including a transmit signal component having the same amplitude as the transmit leakage signal, via a first feedback loop; and
adjusting the phase angle of the amplitude-compensated reference signal to a phase angle 180 degrees out-of-phase with the reference signal, via a second feedback loop, to generate a signal which essentially cancels the transmit leakage signal component of the combined signal, via a second feedback loop.

6. The method of claim 5, wherein the receiver includes a low-noise amplifier, and wherein:
the first feedback loop includes a variable attenuator, a first and a second sampling detector, and a comparator, wherein the reference signal out put from the directional coupler is input to a variable attenuator to provide an attenuated reference signal;
wherein the attenuated reference signal and the combined signal are sampled and respective signal samples thereof are separately input to the comparator;
wherein the output of the comparator is coupled to the variable attenuator to control attenuation of the attenuated reference signal such that the signal samples have equal amplitude; and
the second feedback loop includes a signal combiner and a variable phase shifter coupled to a controller circuit, wherein the phase shifter is coupled to the output of the attenuator, and the combined signal and the output of the phase shifter are input to the combiner;
wherein the output of the combiner is input to the low-noise amplifier, whose output is input to the controller circuit to adjust a phase angle of the attenuated reference signal to an angle 180 degrees out-of phase with respect to the transmit leakage signal component of the combined signal, thereby canceling out the transmit leakage signal component of the combined signal.
